(19) United States
(12) Patent Application Publication
(10) Pub. No.: US 2005/0211991 A1
(43) Pub. Date: Sep. 29, 2005

(54) Light-emitting apparatus and illuminating apparatus

(75) Inventors: Yuki Mori, Gamo-gun (JP); Akira Miyake, Gamo-gun (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/088,238

(22) Filed: Mar. 22, 2005

(30) Foreign Application Priority Data
Mar. 26, 2004 (JP) P2004-092208
Mar. 26, 2004 (JP) P2004-092209

(51) Int. Cl. H01L 27/15; H01L 21/00

(52) U.S. Cl. 257/79; 438/22

(57) ABSTRACT

There is provided a light-emitting apparatus with favorable radiation light intensity, which is excellent in light extraction efficiency, color temperature and color rendering property. The light-emitting apparatus includes a light-emitting element, a base body having, on its top surface, a placement portion for emplacing thereon the light-emitting element, a frame body attached to the top surface of the base body so as to surround the placement portion, a light transmitting member disposed inside the frame body so as to cover the light-emitting element, and phosphors contained in the light transmitting member, which performs wavelength conversion on the light emitted from the light-emitting element. The light transmitting member has a pre-cured viscosity ranging from 0.4 to 50 Pa.s.

### BACKGROUND OF THE INVENTION

1. Field of the Invention

The present invention relates to a light-emitting apparatus and illuminating apparatus for radiating out light that has been emitted from a light-emitting element such as a light-emitting diode and then wavelength-converted by phosphors.

2. Description of the Related Art

FIG. 8 is a sectional view showing a light-emitting apparatus 101 of conventional design for giving forth light of any given color using phosphors 106 which convert light such as near-ultraviolet light or blue-color light emitted from a light-emitting element 104 such as a light-emitting diode (LED) into red-color light, green-color light, blue-color light, yellow-color light or the like. In FIG. 8, the light-emitting apparatus 101 is mainly composed of a base body 102 made of an insulator; a frame body 103; a light transmitting member 105; and the light-emitting element 104. The base body 102 has, at the center of its top surface, a placement portion 102a for emplacing thereon the light-emitting element 104. The base body 102 is also provided with a wiring conductor (not shown) formed of, for example, a metallized wiring line and a lead terminal for electrically conductively connecting within and without the light-emitting apparatus 101 by way of the placement portion 102a and its environs. The frame body 103 is fixedly bonded to the top surface of the base body 102. In the frame body 103, a through hole is drilled in such a way that its upper opening is larger than its lower opening. The frame body 103 has its inner peripheral surface 103a, which defines the through hole, shaped into a reflection surface for reflecting light emitted from the light-emitting element 104. The light transmitting member 105 is charged inside the frame body 103. The light transmitting member 104 contains phosphors 106 which perform wavelength conversion on the light emitted from the light-emitting element 104.

FIG. 9 is a sectional view showing a light-emitting apparatus 111 of conventional design in which any color lights are emitted by two kinds of phosphors 116a, 116b which convert near-ultraviolet light, blue-color light or the like emitted from a light-emitting element 114 such as a light-emitting diode (LED) into light such as red-color light, green-color light, blue-color light, or yellow-color light. In FIG. 9, the light-emitting apparatus 111 is mainly composed of a base body 112 made of an insulator; a frame body 113; a light transmitting member 115; and the light-emitting element 114. The base body 112 has, at the center of its top surface, a placement portion 112a for emplacing thereon the light-emitting element 114. The base body 112 is also provided with a wiring conductor (not shown) formed of, for example a metallized wiring line and a lead terminal for electrically conductively connecting within and without the light-emitting apparatus 111 by way of the placement portion 112a and its environs. The frame body 113 is fixedly bonded to the top surface of the base body 112. In the frame body 113, a through hole is drilled in such a way that its upper opening is larger than its lower opening. The frame body 113 has its inner peripheral surface 113a, which defines the through hole, shaped into a reflection surface for reflecting light emitted from the light-emitting element 114. The light transmitting member 105 is charged inside the frame body 113. The light transmitting member 104 contains phosphors 116a, 116b which perform wavelength conversion on the light emitted from the light-emitting element 114. Optionally, the two kinds of phosphors 116a, 116b are hereinafter collectively referred to as phosphors 116.

The base bodies 102, 112 are made of ceramics such as sintered aluminum oxide (alumina ceramics), sintered aluminum nitride, sintered mullite or glass ceramics, or a resin material such as epoxy resin. In a case where the base bodies 102, 112 are made of a ceramics material, on the top surface thereof is formed a wiring conductor (not shown) by firing a metal paste of tungsten (W) or molybdenum (Mo)-manganese (Mn) at high temperature. On the other hand, in a case where the base bodies 102, 112 are made of a resin material, a molded lead terminal made of copper (Cu) or an iron (Fe)-nickel (Ni) alloy is fixedly arranged within the base bodies 102, 112.

In the frame bodies 103, 113, shaped like frames, a through hole is drilled in such a way that its upper opening is larger than its lower opening. On the inner peripheral surfaces 103a, 113a of the frame bodies 103, 113 which define the through hole, are formed a reflection surface for reflecting light. Specifically, the frame bodies 103, 113 are formed of a metal material such as aluminum (Al) and an Fe—Ni-cobalt (Co) alloy, or a ceramics material such as alumina ceramics, or a resin material such as epoxy resin, by a cutting process or a molding technique such as die-molding or extrusion.

The reflection surface of the frame bodies 103, 113 are formed by polishing and flattening the inner peripheral surfaces 103a, 113a, or formed by coating a metal such as Al on the inner surfaces 103a, 113a of the frame bodies 103, 113 by means of vapor deposition or plating. The frame bodies 103, 113 are finally joined to the top surface of the base bodies 102, 112, with use of a bonding material such as solder, a brazing filler material such as silver (Ag) paste, or a resin adhesive, in such a way that the placement portions 102a, 112a are surrounded by the inner surfaces 103a, 113a of the frame bodies 103, 113.

As the light-emitting elements 104, 114 are used light-emitting diodes (LED) or the like which are constituted by forming light-emitting layer on, for example, a sapphire substrate, for example, by the liquid-phase growth method or MOCVD method. The examples of materials used for the light-emitting layer include a semiconductor such as: a gallium (Ga)-an aluminum (Al)-nitride (N) compound; a zinc (Zn)-sulfur (S) compound; a Zn-selenium (Se) compound; a silicon (Si)-carbon (C) compound; a Ga-phosphorus (P) compound; a Ga—Al-arsenic (As) compound; an Al-indium (In)—Ga—P compound; an In—Ga—N compound; a Ga—N compound; and an Al—In—Ga—N compound. The semiconductor may have a homo junction structure, a heterojunction structure, or a double-hetero structure including an MIS junction or pn junction. The luminescence wavelength of the light-emitting elements 104, 114 can be selected according to the material used for the semiconductor layer and its mix crystal ratio, for example, in a range from ultraviolet to infrared regions.

The phosphors 106, 116 are excited by visible or ultraviolet light with the luminescence wavelength emitted from the light-emitting elements 104, 114, and used for converting the light into light with longer wavelength. Thus, various materials may be used in consideration of the luminescence wavelength of the light emitted from the light-emitting elements 104, 114, as well as desired light emitted from the light-emitting apparatuses 101, 111. Especially, the light-emitting apparatuses are allowed to emit white light under conditions where the light emitted from the light-emitting elements 104, 114 and the light emitted from the phosphors 106, 116 emitting fluoresce by being excited by the light emitted from the light-emitting elements 104, 114 are in a complementary-color relation to each other. The preferred examples of the phosphors 106, 116 in use include: a cerium (Ce)-activated yttrium aluminum garnet-based phosphor; a perylene derivative; copper (Cu).Al-activated zinc cadmium sulfide; manganese (Mn)-activated magnesium oxide; and manganese (Mn)-activated titanium oxide. The phosphors 106, 116 may be formed of either a single substance or a mixture of two or more different substances.

In general, the phosphors 106, 116 are made in the form of a fine powder. Therefore, it is difficult for the phosphors 106, 116 to cover the light-emitting elements 104, 114 on their own. In light of this, the phosphors 106, 116 are usually mixed into the light transmitting members 105, 115 made of resin or the like material. The mixture is so shaped as to cover the light-emitting elements 104, 114 and is then subjected to a heat-hardening process, whereupon the light transmitting members 106, 116 containing the phosphors 106, 116 can be cured. For example, the phosphors 106, 116 are admixed in the light transmitting members 105, 115 made of epoxy resin, silicone resin, or the like. Then, the light transmitting members 105, 115 containing the phosphors 106, 116 are so charged inside of the frame bodies 103, 113 as to cover the light-emitting elements 104, 114 from above, and is then cured with heat, thereby constituting a phosphor layer.

As shown in FIG. 8, in preparing the phosphors 106 to be admixed in the light transmitting member 105, by making an adjustment to the mixing ratio of the phosphors 106 of primary colors: red; blue; and green, it is possible to set a color temperature without restraint. For example, as the phosphor 106 for red-color light emission, a phosphor having the composition of La₂O₂S:Eu (Eu-doped La₂O₂S) is used. As the phosphor 106 for green-color light emission, a phosphor having the composition of ZnS:Cu, Al is used. As the phosphor 106 for blue-color light emission, a phosphor having the composition of (BaMgAl)₁₀O₁₂:Eu is used.

Then, the light-emitting elements 104, 114 are mounted on the placement portions 102a, 112a by an adhesive (not shown) having conductivity, such as solder or Ag paste, and the light-emitting elements 104, 114 are electrically connected to the wiring conductor (not shown) arranged near the placement portions 102a, 112a by way of a bonding wire (not shown). After that, the light transmitting members 105, 115 such as epoxy resin or silicone resin that contains the phosphors 106, 116 are charged inside the frame bodies 103, 113 by an injector such as a dispenser so as to cover the light-emitting elements 104, 114, followed by performing a heat-hardening process in an oven. Hereupon, the desired light-emitting apparatuses 101, 111 are realized that are capable of producing light having a desired wavelength spectrum by subjecting the light emitted from the light-emitting elements 104, 114 to wavelength conversion effected by the phosphors 106, 116.

Related arts are disclosed in Japanese Unexamined Patent Publications JP-A 2003-234513, JP-A 2003-298116, and JP-A 2002-314142.

However, the conventional light-emitting apparatus shown in FIG. 8 poses the following problems. After the phosphors 106 are admixed in the light transmitting member 105, the light transmitting member 105 is charged inside the frame 103 and is then cured with heat. At this time, the phosphors 106 precipitate on the bottom side of the light transmitting member 105, and concurrently the phosphors 106 covers the surface of the light-emitting element 104. As a result, the light emitted from the light-emitting element 104 is confined by the phosphors 106, which leads to an undesirable decrease in the light extraction efficiency (the efficiency of taking out the light emanating from the light-emitting layer of the light-emitting element 104). Furthermore, the precipitates of the phosphors 106 are piled up in strata. This causes the upper phosphors 106 to interfere with propagation of light that has been wavelength-converted by the lower phosphors 106, in consequence whereof there results an undesirable decrease in the radiation light intensity in the light-emitting apparatus.

The second problem is occurrence of voids. After the light transmitting member 105 is charged inside the frame 103, a heat-hardening process is performed thereon. At this time, air finds its way into the light transmitting member 105, which causes a void. If the light emitted from the light-emitting element 104 is absorbed by the void, the radiation light intensity will be decreased. Furthermore, if the void cuts off the light, the phosphor 106 cannot be uniformly radiated with the light, which results in color unevenness or a failure in attaining the desired color temperature and color rendering property.

Further, the conventional light-emitting apparatus 111 shown in FIG. 9 poses the following problem. Of the phosphors 116, the phosphors 116a of higher specific gravity are prone to converge on the bottom side of the light transmitting member 115, whereas the phosphors 116b of lower specific gravity are prone to converge on the upper side of the light transmitting member 115 or converge above the phosphors 116a of higher specific gravity. As a result, of the phosphors 116 of two or more types, some are radiated heavily with the excitation light emitted from the light-emitting element 114, but others are radiated poorly therewith, in consequence whereof there results color-temperature deviation. This makes it difficult to control the color temperature properly.

### SUMMARY OF THE INVENTION

The invention has been devised in view of the above-described problems with the related art, and accordingly its object is to provide a light-emitting apparatus that succeeds in exhibiting higher radiation light intensity, in preventing unevenness in color of light emitted therefrom, in providing stable color rendering property and color temperature, and further in stably radiating the light with desired color temperature even when a plurality of phosphors are used.

The invention provides a light-emitting apparatus comprising:
a light-emitting element;
a base body having, on its top surface, a placement portion for emplacing thereon the light-emitting element;
a frame body attached to the top surface of the base body so as to surround the placement portion;
a light transmitting member disposed inside the frame body so as to cover the light-emitting element; and
phosphors contained in the light transmitting member, which performs wavelength conversion on the light emitted from the light-emitting element,
wherein the light transmitting member has a pre-cured viscosity ranging from 0.4 to 50 Pa.s.

In the invention, it is preferable that the phosphors have a density ranging from 3.8 to 7.3 g/cm³.

In the invention, it is preferable that the phosphors are composed of a plural kinds of substances.

In the invention, it is preferable that the phosphors are so prepared that a difference in specific gravity between the ones of highest specific gravity and the ones of lowest specific gravity is kept at 3.5 or below.

In the invention, it is preferable that a phosphor layer made of the light transmitting member containing the phosphors has a thickness ranging from 0.3 to 1.5 mm and a volume of 1/24 to 1/6 times as much as a volume of the light transmitting member.

In the invention, it is preferable that the phosphors have an average grain diameter ranging from 1 to 50 μm.

In the invention, it is preferable that the light-emitting element is designed to emit light exhibiting an emission spectrum having a peak wavelength at 450 nm or below, and that the light transmitting member is made of silicone resin or fluorine resin.

The invention provides a method for manufacturing the light-emitting apparatus, comprising the steps of:
attaching a frame body on a top surface of a base body having a placement portion for emplacing a light-emitting element, so as to surround the placement portion;
emplacing the light-emitting element on the placement portion; and
uniformly admixing phosphors in a light transmitting member having a pre-cured viscosity ranging from 0.4 to 50 Pa.s, charging the light transmitting member containing the phosphors inside the frame body so as to cover a surface of the light-emitting element, and thereafter curing the light transmitting member within ten minutes.

The invention provides an illuminating apparatus constructed by setting up the above-described light-emitting apparatus in a predetermined arrangement.

According to the invention, a light-emitting apparatus comprises a light-emitting element; a base body having, on its top surface, a placement portion for emplacing thereon the light-emitting element; a frame body attached to the top surface of the base body so as to surround the placement portion; a light transmitting member disposed inside the frame body so as to cover the light-emitting element; and phosphors contained in the light transmitting member, which performs wavelength conversion on the light emitted from the light-emitting element. The light transmitting member has a pre-cured viscosity ranging from 0.4 to 50 Pa.s. Furthermore, the phosphors have a density ranging from 3.8 to 7.3 g/cm³. In this constitution, during curing of the light transmitting member charged inside the frame body with heat, it is possible to minimize precipitation of the phosphors, and thereby prevent the phosphors from covering the surface of the light-emitting element. As a result, a decrease in the light extraction efficiency in relation to the light-emitting element, as well as light propagation loss ascribable to the phosphors, can be prevented successfully; wherefore the radiation light intensity can be increased in the light-emitting apparatus.

Moreover, during charging of the light transmitting member inside the frame body, since the light transmitting member possesses a viscosity of appropriate level, the air trapped in the light transmitting member can be released successfully. This helps prevent appearance of a void in the light transmitting member effectively. As a result, several advantages are gained: the radiation light intensity can be increased; unevenness in color can be avoided; and the desired color temperature and color rendering property can be attained.

According to the invention, in a case where the phosphors are composed of plural kinds of substances, even if the phosphors differ from one another in specific gravity, it is possible to lessen floating and precipitation of the phosphors. Therefore, the phosphors can be admixed and dispersed uniformly in the light transmitting member. Further, during charging of the light transmitting member inside the frame body, it is possible to release bubbles into the air by exploiting a buoyant force with ease. The bubbles remain in the gap between the base body, the frame body and the light-emitting element, and in the light transmitting member and the bonding material (not shown). As a result, it is possible to realize a light-emitting apparatus that is excellent in illumination characteristics in which unevenness in color and unbalanced illumination distribution can be avoided on the light-emitting surface and on a to-be-irradiated surface, and light is inhibited from scattering within the light transmitting member.

According to the invention, in a case where the phosphors are so prepared that the difference in specific gravity between the ones of highest specific gravity and the ones of lowest specific gravity is kept at 3.5 or below, it is possible to reduce the difference in ascent rate and precipitation rate among the phosphors resulting from the specific-gravity difference, and thereby avoid unbalanced gathering of the phosphors in the light transmitting member more effectively. As a result, the phosphors can be dispersed uniformly in the light transmitting member, whereby making it possible to realize a light-emitting apparatus that provides stable color characteristics.

According to the invention, a phosphor layer made of the light transmitting member containing the phosphors has a thickness ranging from 0.3 to 1.5 mm and a volume of 1/24 to 1/6 times as much as a volume of the light transmitting member. This makes it possible to prevent a light output from getting smaller by a decrease of light propagation loss ascribable to diffused reflection inside the phosphors layer and an increase of the density of the phosphors of the light transmitting member and by a decrease of phosphors excited by light emitted from the light-emitting element.

According to the invention, the phosphors have an average grain diameter ranging 1 to 50 μm. In a case where the grain diameter is more than 50 μm, a rate that the fluorescent light emitted from the phosphors is interfered by the phosphors in the light transmitting member becomes larger, whereby the phosphors on their own becomes impediments to the light propagation. As a result, it becomes difficult for the fluorescent light to be put out to the outside of the light-emitting apparatus, and the light intensity is decreased in the light-emitting apparatus with ease.

On the other hand, in a case where the grain diameter is less than 1 μm, a probability that the light from light-emitting element propagating in the light transmitting member is absorbed in the phosphors becomes smaller, and the light from light-emitting element is put out to the outside with ease without undergoing wavelength conversion through between the phosphors. As a result, color variations in the light output from the light-emitting apparatus tend to become larger. Therefore, limiting the average grain diameter of the phosphors to a range of 1 to 50 μm prevents the decrease of light intensity and the large color variations in the output light.

According to the invention, the light-emitting element is designed to emit light exhibiting an emission spectrum having a peak wavelength at 450 nm or below. Moreover, the light transmitting member is made of silicone resin or fluorine resin. In this way, several advantages are gained: an undesirable decrease in the transmittance of the light transmitting member ascribable to the high-energy light of short wavelength emitted from the light-emitting element can be prevented effectively; an undesirable decrease in the strength of bonding between the light-emitting element and the base body can be prevented effectively; an undesirable decrease in the strength of bonding between the base body and the frame body can be prevented effectively; and the phosphors are able to allow conversion into light of varying colors, for example white-color light and blue-color light, etc.

According to the invention, a method for manufacturing the light-emitting apparatus comprises the steps of: attaching a frame body on a top surface of a base body having a placement portion for emplacing a light-emitting element, so as to surround the placement portion; emplacing the light-emitting element on the placement portion; and uniformly admixing phosphors in a light transmitting member having a pre-cured viscosity ranging from 0.4 to 50 Pa.s, charging the light transmitting member containing the phosphors inside the frame body so as to cover a surface of the light-emitting element, and thereafter curing the light transmitting member within ten minutes. With this manufacturing method, the light transmitting member can be cured while the phosphors being dispersed uniformly without precipitating on the bottom side thereof. As a result, it is possible to realize a light-emitting apparatus that provides stable color rendering property and color temperature while minimizing unevenness in color of the light emitted from the light-emitting apparatus.

According to the invention, the illuminating apparatus is constructed by setting up the above-described light-emitting apparatus in a predetermined arrangement. In this illuminating apparatus, light emission is effected by exploiting recombination of electrons in the light-emitting element composed of a semiconductor. Thus, the illuminating apparatus can be made compact and have the advantage, in terms of power saving and long lifetime, over a conventional illuminating apparatus for effecting light emission through electrical discharge. As a result, variation in the center wavelength of the light emitted from the light-emitting element can be suppressed; wherefore the illuminating apparatus is capable of irradiating light with stable radiation light intensity and stable radiation light angle (luminous intensity distribution) for a longer period of time. Moreover, unevenness in color and unbalanced illumination distribution can be prevented from occurring on a to-be-irradiated surface.

Moreover, by setting up the light-emitting apparatuses of the invention in a predetermined arrangement as light sources, followed by arranging around the light-emitting apparatuses such a component as is optically designed in a given configuration, for example a reflection jig, an optical lens, and a light diffusion plate, it is possible to realize an illuminating apparatus which is capable of emitting light with given luminous intensity distribution.

### BRIEF DESCRIPTION OF THE DRAWINGS

Other and further objects, features, and advantages of the invention will be more explicit from the following detailed description taken with reference to the drawings wherein:

FIG. 1 is a sectional view showing a light-emitting apparatus in accordance with a first embodiment of the invention;

FIG. 2 is a sectional view showing a light-emitting apparatus in accordance with a second embodiment of the invention;

FIG. 3 is a sectional view showing a light-emitting apparatus in accordance with a third embodiment of the invention;

FIG. 4 is a top view showing an illuminating apparatus in accordance with a fourth embodiment of the invention;

FIG. 5 is a sectional view of the illuminating apparatus shown in FIG. 4;

FIG. 6 is a top view showing an illuminating apparatus in accordance with a fifth embodiment of the invention;

FIG. 7 is a sectional view of the illuminating apparatus shown in FIG. 6;

FIG. 8 is a sectional view showing a conventional light-emitting apparatus; and

FIG. 9 is a sectional view showing another conventional light-emitting apparatus.

### DETAILED DESCRIPTION OF THE PREFERRED EMBODIMENTS

Now referring to the drawing, preferred embodiments of the invention are described below.

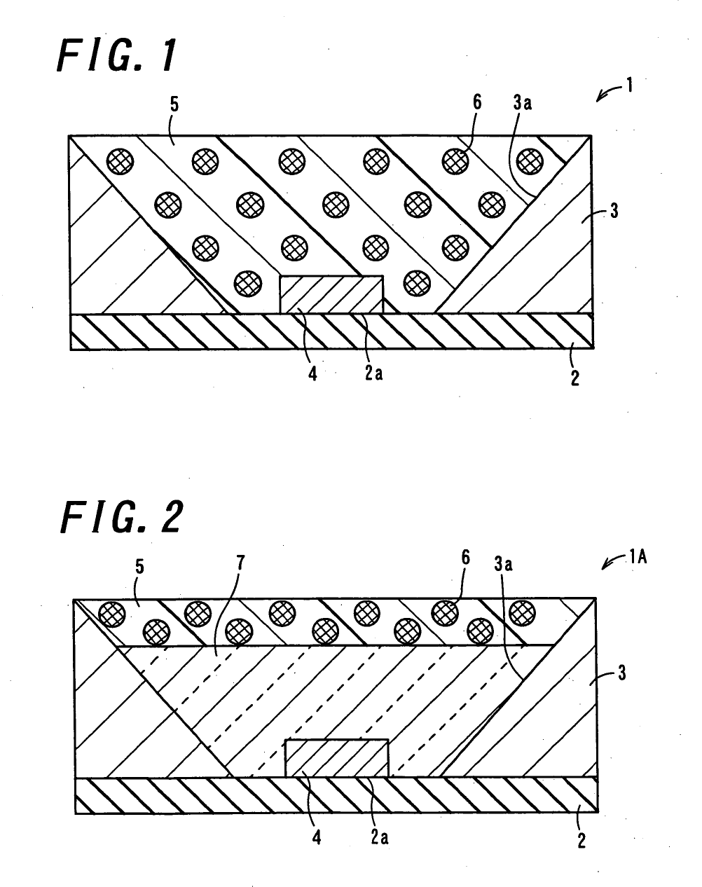

Now, a detailed description will be given below as to a light-emitting apparatus according to the invention. FIG. 1 is a sectional view showing the light-emitting apparatus 1 in accordance with a first embodiment of the invention. The light-emitting apparatus 1 comprises a base body 2, a frame body 3, a light-emitting element 4, a light transmitting member 5, and phosphors 6. Thus, the light-emitting apparatus 1 for housing therein a light-emitting element 4 is configured.

The base body 2 has, on its top surface, a placement portion 2a for emplacing thereon the light-emitting element 4. The frame body 3 is attached to the top surface of the base body 2 so as to surround the placement portion 2a. The frame body 3 has its inner peripheral surface shaped into a reflection surface for reflecting light emitted from the light-emitting element 4. The light-emitting element 4 is emplaced on the placement portion 2a. The light transmitting member 5 comprises the phosphors 6 for performing wavelength conversion on the light emitted from the light-emitting element 4.

The base body 2 is formed as an insulator by using a ceramics material such as sintered aluminum oxide, sintered aluminum nitride, sintered mullite, or glass ceramics, or a resin material such as epoxy resin or liquid crystal polymer. The base body 2 serves also as a supporting member for supporting the light-emitting element 4 emplaced on the placement portion 2a formed on the top surface thereof.

Moreover, on the surface and in the interior of the base body 2 are formed metallized wiring layers (not shown) made of powder of a metal such as W, Mo, or Mn for electrically conductively connecting within and without the light-emitting apparatus 1. The electrode of the light-emitting element 4 is electrically connected to the metallized wiring layer exposed at the placement portion 2a formed on the top surface of the base body 2 with use of a bonding material such as Au—Sn eutectic solder or a bonding wire. Then, a lead terminal (not shown) made of a metal such as Cu or an Fe—Ni alloy is bonded to the metallized wiring layer exposed on the outer surface, for example the under surface, of the base body 2.

In the case of forming the base body 2 from a ceramics material, on the top surface thereof is formed a wiring conductor (not shown) by firing a metal paste of W or Mo—Mn at high temperature. On the other hand, in the case of forming the base body 2 from a resin material, a molded lead terminal made of Cu or an Fe—Ni alloy is fixedly arranged within the base body 2. The frame body 3 is bonded to the top surface of the base body 2 so as to surround the placement portion 2a with use of solder, or a brazing filler material such as an Ag paste, or a resin adhesive such as epoxy resin.

It is preferable that the metallized wiring layer has its exposed surface coated with a highly corrosion-resistant metal such as Ni and gold (Au) in the thickness ranging from 1 to 20 μm. This makes it possible to protect the metallized wiring layer against oxidative corrosion effectively, and also to strengthen the connection between the metallized wiring layer and the light-emitting element 4, as well as the connection between the metallized wiring layer and the bonding wire. Accordingly, the exposed surface of the metallized wiring layer should preferably be coated with a 1 to 10 μm-thick Ni plating layer and a 0.1 to 3 μm-thick Au plating layer successively by the electrolytic plating method or electroless plating method.

Moreover, onto the top surface of the base body 2 is attached the frame body 3 so as to surround the light-emitting element 4 emplaced on the placement portion 2a formed on the top surface of the base body 2, with use of an inorganic adhesive such as solder, sol-gel glass, or low-melting-point glass, or an organic adhesive such as epoxy resin. Note that the inorganic adhesive is more desirable in terms of durability.

In order to reflect the light emitted from the side surface of the light-emitting element 4 in an upward direction, it is preferable that the frame body 3 is shaped like a frame, in which a through hole is drilled in such a way that its upper opening is larger than its lower opening, and a reflection surface for reflecting light is formed on the inner peripheral surface 3a of the frame body 3 defining the through hole. Specifically, the frame body 3 is formed of a metal material such as Al and an Fe—Ni—Co alloy, or a ceramics material such as alumina ceramics, or a resin material such as epoxy resin, with a cutting process or a molding technique such as die-molding and extrusion.

In a case where the frame body 3 is made of a high-reflectivity metal such as Al, Ag, Au, platinum (Pt), titanium (Ti), chromium (Cr), and Cu, its inner peripheral surface of the frame body 3 is formed by subjecting the frame body 3 to cutting, die-molding, or the like process. Preferably, the inner peripheral surface of the frame body 3 is flattened into a reflection surface with a surface-polishing process such as electrolytic polishing or chemical polishing.

On the other hand, in a case where the frame body 3 is made of an insulative material such as ceramics and resin, its inner peripheral surface may be formed by laminating a thin film of a high-reflectivity metal such as Al, Ag, Au, Pt, Ti, Cr, and Cu on the frame body 3 by means of plating or vapor deposition (this is true also for the case where the frame body 3 is made of a metal) In a case where the inner peripheral surface is formed of a metal that is susceptible to discoloration resulting from oxidation, such as Ag and Cu, it is preferable to laminate on its surface for example a 1 to 10 μm-thick Ni plating layer and a 0.1 to 3 μm-thick Au plating layer successively by the electrolytic plating method or electroless plating method. This helps enhance the corrosion resistance of the inner peripheral surface.

Alternatively, in the frame body 3, an arithmetic average roughness Ra at the top of the inner peripheral surface is preferably adjusted to fall in a range of 0.004 to 4 μm. This allows the frame body 3 to reflect the light emitted from the light-emitting element 4 satisfactorily. If Ra exceeds 4 μm, the light emitted from the light-emitting element 4 cannot be reflected uniformly, and thereby diffuse reflection takes place within the frame body 3. By contrast, if Ra is less than 0.004 μm, it will be difficult to form such a desired reflection surface with stability and high efficiency.

The light-emitting element 4 is composed of a compound semiconductor, such as a nitride-based compound semiconductor, formed by stacking a buffer layer, an n-type layer, a light-emitting layer, and a p-type layer made of GaN, AlGaN, InGaN, or the like substance one by one on a monocrystalline substrate such as a sapphire substrate.

The light-emitting element 4 is, at the electrode formed on its top surface, electrically connected to the wiring conductor disposed on the top surface of the base body 2 by means of the wire bonding method. In the alternative, the light-emitting element 4 is, at the electrode formed on its lower side, electrically connected to the wiring conductor disposed on the placement portion 2a of the base body 2 by means of the flip-chip bonding method, with use of a solder bump or a conductive adhesive such as a conductive paste. Then, the light transmitting member 5, which contains the phosphors 6 for performing wavelength conversion on the light emitted from the light-emitting element 4, is charged inside the frame body 3 so as to cover the light-emitting element 4. Note that the flip-chip bonding method is more desirable for the connection of the light-emitting element 4. With the method, the wiring conductor can be disposed immediately below the light-emitting element 4. This eliminates the need to secure an extra space for disposing the wiring conductor around the light-emitting element 4 on the top surface of the base body 2. Hence, it never occurs that the light emitted from the light-emitting element 4 is absorbed in the space of the base body 2 secured for the wiring conductor. Accordingly, an undesirable decrease in the radiation light intensity can be avoided effectively.

In the invention, the light transmitting member 5 ranges in viscosity from 0.4 to 50 Pa.s before it is cured, with the phosphors 6 admixed therein (hereafter referred to as “pre-cured viscosity”). The phosphors 6 to be contained in the light transmitting member 5 range in density from 3.8 to 7.3 g/cm³. In this way, during curing of the light transmitting member 5 charged inside the frame body 3 with heat, it is possible to minimize precipitation of the phosphors 6, and thereby prevent the phosphors 6 from covering the surface of the light-emitting element 4. As a result, a decrease in the light extraction efficiency in relation to the light-emitting element 4, as well as light propagation loss ascribable to the phosphors 6, can be prevented successfully; wherefore the radiation light intensity can be increased in the light-emitting apparatus.

Moreover, during charging of the light transmitting member 5 inside the frame body 3, since the light transmitting member 5 possesses a viscosity of appropriate level, the air trapped in the light transmitting member 5 can be released successfully. This helps prevent appearance of a void in the light transmitting member 5 effectively. As a result, several advantages are gained: the radiation light intensity can be increased; unevenness in color can be avoided; and the desired color temperature and color rendering property can be attained.

In a case where the pre-cured viscosity of the light transmitting member 5 falls in a range from 0.4 to 50 Pa.s and the density of the phosphors 6 is less than 3.8 g/cm³, the phosphors 6 precipitate within the light transmitting member 5 at a lower rate. In this case, much time needs to be spent in dispersing the phosphors 6 uniformly in the light transmitting member 5, and also the uniform dispersion may be difficult. As a result, in the light transmitting member 5, the density of the phosphors 6 varies from part to part, which may cause unevenness in color and unbalanced illumination distribution on a surface to be irradiated with the fluorescence having been wavelength-converted by the phosphors 6.

In a case where the pre-cured viscosity of the light transmitting member 5 falls in a range from 0.4 to 50 Pa.s and the density of the phosphors 6 is greater than 7.3 g/cm³, even if the phosphors 6 are dispersed uniformly in the light transmitting member 5, the phosphors 6 precipitate at a greater rate due to the unduly large density. Therefore, the precipitates of the phosphors 6 are prone to accumulate in strata before the light transmitting member 5 is cured, and thus the phosphors 6 tend to cover the surface of the light-emitting element 4 closely. As a result, the phosphors 6 may cause the light emitted from the light-emitting element 4 to be confined therewithin, which leads to an undesirable decrease in the external quantum efficiency. Furthermore, the upper phosphors 6 interfere with propagation of the light that has been wavelength-converted by the lower phosphors 6, in consequence whereof there results an undesirable decrease in radiation light intensity in the light-emitting apparatus.

On the other hand, in a case where the density of the phosphors 6 falls in a range from 3.8 to 7.3 g/cm³ and the viscosity of the light transmitting member 5 exceeds 50 Pa.s, the phosphors 6 precipitate within the light transmitting member 5 at a lower rate. In this case, much time needs to be spent in dispersing the phosphors 6 uniformly in the light transmitting member 5, and also the uniform dispersion may be difficult. As a result, in the light transmitting member 5, the density of the phosphors 6 varies from part to part, which may cause unevenness in color and unbalanced illumination distribution on a surface to be irradiated with the fluorescence having been wavelength-converted by the phosphors 6.

In a case where the density of the phosphors 6 falls in a range from 3.8 to 7.3 g/cm³ and the pre-cured viscosity of the light transmitting member 5 is less than 0.4 Pa.s, the phosphors 6 are prone to precipitate at a greater rate due to the unduly low light transmitting member 5's viscosity. As a result, even if the phosphors 6 are dispersed uniformly in the light transmitting member 5, the precipitates of the phosphors 6 may be piled up in strata before the light transmitting member 5 is cured, and thus the phosphors 6 tend to cover the surface of the light-emitting element 4 closely. As a result, the phosphors 6 may cause the light emitted from the light-emitting element 4 to be confined therewithin, which leads to an undesirable decrease in the external quantum efficiency. Furthermore, the upper phosphors 6 interfere with propagation of the light that has been wavelength-converted by the lower phosphors 6, in consequence whereof there results an undesirable decrease in the radiation light intensity in the light-emitting apparatus.

In order to inhibit improper precipitation of the phosphors 6 within the light transmitting member 5, it is preferable that the light transmitting member 5, now containing the phosphors 6 which range in density from 3.8 to 7.3 g/cm³ admixed therein uniformly, is cured within ten minutes after it is arranged inside the frame body 3 so as to cover the surface of the light-emitting element 4. As a result, the light transmitting member 5 can be cured, with the phosphors 6 kept dispersed uniformly. This makes it possible to realize a light-emitting apparatus that provides excellent illumination characteristics such as stable color temperature and color rendering property while minimizing unevenness in color and unbalanced illumination distribution.

It is preferable that a phosphor layer made of the light transmitting member 5 containing the phosphors 6 has a thickness ranging from 0.3 to 1.5 mm. In a case where a thickness of the phosphor layer is less than 0.3 mm, there increases light emitted from the light-emitting element to be put out to the outside of the light-emitting element without undergoing wavelength conversion at the phosphors 6. In other words, a light output of the light-emitting element becomes smaller due to a decrease of the phosphors excited by light emitted from the light-emitting element. In a case where a thickness of the phosphor layer exceeds 1.5 mm, light propagation loss ascribable to diffused reflection inside the phosphors layer becomes larger, and the light output of the light-emitting element becomes smaller.

Moreover, it is preferable that a volume of the phosphors 6 is 1/24 to 1/6 times as much as that of the light transmitting member 5. In a case where a volume of the phosphors 6 is less than 1/24 times as much as that of the light transmitting member 5, the density of the phosphors 6 in the light transmitting member 5 becomes smaller, and the light conversion efficiency of the phosphors 6 is decreased. In this case, there increases light emitted form the light-emitting element, which is transmitted to outside of the light-emitting apparatus without undergoing wavelength conversion at the phosphors 6. In other words, an amount of visible light from the phosphors 6 is decreased, and an output of the light-emitting apparatus becomes smaller. In a case where a volume of the phosphors 6 exceeds 1/6 times as much as that of the light transmitting member 5, the density of the phosphors 6 in the light transmitting member 5 becomes larger, and the phosphors 6 on their own becomes impediments to light propagation so that propagation loss is increased. Therefore, it becomes difficult for light of the phosphors 6 to be efficiently put out to the outside of the light-emitting apparatus.

It is preferable that the phosphors have an average grain diameter ranging 1 to 50 μm. In a case where the grain diameter is more than 50 μm, a rate that the fluorescent light emitted from the phosphors is interfered by the phosphors in the light transmitting member becomes larger, whereby the phosphors on their own becomes impediments to the light propagation. As a result, it becomes difficult for the fluorescent light to go out to the outside of the light-emitting apparatus, and the light intensity is decreased in the light-emitting apparatus with ease.

On the other hand, in a case where the grain diameter is less than 1 μm, a probability that the light from light-emitting element propagating in the light transmitting member is absorbed in the phosphors becomes smaller, and the light from light-emitting element goes out to the outside with ease without undergoing wavelength conversion through between the phosphors. As a result, color variations in the light output from the light-emitting apparatus tends to become larger.

If the light transmitting member 5 containing the uniformly dispersed phosphors 6 is left to cure for more than ten minutes, the phosphors 6 are prone to precipitate on the bottom side of the light transmitting member 5. As a result, the precipitates of the phosphors 6 cover the surface of the light-emitting element 4 closely. This causes the light emitted from the light-emitting element 4 to be confined within the phosphors 6, which leads to an undesirable decrease in the external quantum. Furthermore, the upper phosphors 6 interfere with propagation of the light that has been wavelength-converted by the lower phosphors 6, in consequence whereof there results an undesirable decrease in the radiation light intensity in the light-emitting apparatus.

It is preferable that the light transmitting member 5 is made of a material that is not much different in refractive index from the light-emitting element 4 and exhibits high transmittance in regions ranging from ultraviolet light to visible light. For example, the light transmitting member 5 is made of transparent resin such as silicone resin, epoxy resin, and urea resin, or low-melting-point glass, or sol-gel glass. This makes it possible to realize a light-emitting apparatus in which occurrence of light reflection loss resulting from the difference in refractive index between the light transmitting member 5 and the light-emitting element 4 can be avoided effectively. With such a light-emitting apparatus 1, light is allowed to radiate out highly efficiently with the desired radiation intensity and radiation-angle distribution.

The light-emitting apparatus 1 embodying the invention is fabricated as follows. Firstly, the light-emitting element 4 is emplaced on the placement portion 2a of the base body 2. Then, the light-emitting element 4 is electrically connected to the wiring conductor by means of, for example the wire bonding method or the flip-chip bonding method. After that, the light transmitting member 5 containing the phosphors 6 is charged inside the frame body 3 so as to cover the light-emitting element 4, followed by performing a heat-hardening process. Eventually, the light-emitting apparatus is capable of producing light having the desired wavelength spectrum by subjecting the light emitted from the light-emitting element 4 to wavelength conversion effected by the phosphors 6.

FIG. 2 is a sectional view showing a light-emitting apparatus 1A in accordance with a second embodiment of the invention. As shown in FIG. 2, the light-emitting apparatus 1A may be so configured that a transparent member 7 is charged into the frame body 3 before charging the light transmitting member 5 containing the phosphors 6. In this case, the light transmitting member 5 containing the phosphors 6 is poured on the top surface of the transparent member 7. This makes it possible to increase the external quantum efficiency of the light emitted from the light-emitting element 4, and also to increase the light conversion efficiency of the phosphors 6. As a result, the radiation light intensity can be increased in the light-emitting apparatus while minimizing unevenness in color and unbalanced illumination distribution on a to-be-irradiated surface.

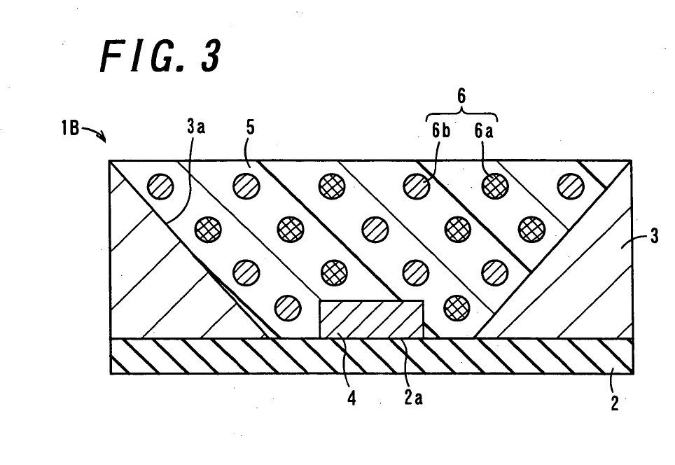

FIG. 3 is a sectional view showing a light-emitting apparatus 1B in accordance with a third embodiment of the invention. The light-emitting apparatus 1B in accordance with the embodiment has a same configuration as that of the light-emitting apparatus 1 in accordance with the first embodiment shown in FIG. 1 except that a plural kinds (two kinds in the embodiment) of phosphors 6a, 6b are used in the light-emitting apparatus 1B. In the embodiment, the components corresponding to the configuration of the aforementioned embodiment will be denoted by the same reference numeral and a description thereof will be omitted. Optionally, the plural kinds of phosphors 6a, 6b are hereinafter collectively referred to as mere phosphors 6.

In the light-emitting apparatus 1B of the embodiment, the pre-cured viscosity of the light transmitting member 5 is adjusted to fall in a range from 0.4 to 50 Pa.s, and the phosphors 6 are composed of a plural kinds of substances. This makes it possible to lessen precipitation and unbalanced gathering of the phosphors 6 and thereby allow the phosphors 6 to be admixed and dispersed uniformly in the light transmitting member 5. Specifically, if the pre-cured viscosity of the light transmitting member 5 is less than 0.4 Pa.s, as relative to the viscosity of the light transmitting member 5, the phosphors 6a of higher specific gravity precipitate at a greater rate than the phosphors 6b of lower specific gravity do. This makes it difficult to maintain the phosphors 6a and 6b in a uniformly-dispersed state from the bottom to the top of the light transmitting member 5. In this case, after a certain length of time has elapsed, the phosphors 6a precipitate on the bottom side of the light transmitting member 5, and the precipitates cover the surface of the light-emitting element 4. As a result, the light emitted from the light-emitting apparatus 1 undergoes color-temperature deviation, or the light emitted from the light-emitting element 4 is confined by the phosphors 6, which leads to a sharp decrease in the efficiency of taking light out of the light-emitting element 4, namely, the external quantum efficiency.

By contrast, if the pre-cured viscosity of the light transmitting member 5 exceeds 50 Pa.s, the light transmitting member 5 exhibits unduly high viscosity. This makes it difficult to allow the phosphors 6a and 6b to be dispersed uniformly in the entire light transmitting member 5. Moreover, it becomes also difficult to release bubbles into the air by exploiting a buoyant force at the time of charging the light transmitting member 5 inside the frame body 3. The bubbles remain in the gap between the light-emitting element 4, the base body 2, and the frame body 3, and in the light transmitting member 5, and in the bonding material (not shown). As a result, the light-emitting apparatus 1 suffers from unevenness in color and unbalanced illumination distribution on its light-emitting surface or on a to-be-irradiated surface. Furthermore, the bubbles trapped in the light transmitting member 5 cause light to scatter, which gives rise to a larger loss in the light transmitting member 5. Correspondingly, the radiation light intensity is decreased in the light-emitting apparatus 1.

In the invention, it is preferable that the phosphors 6 are so prepared that the difference in specific gravity between the ones of highest specific gravity (the phosphors 6a) and the ones of lowest specific gravity (the phosphors 6b) is kept at 3.5 or below. This makes it possible to reduce the difference in ascent rate and precipitation rate among the phosphors 6 resulting from the specific-gravity difference, and thereby avoid unbalanced gathering of the phosphors 6 in the light transmitting member 5. Specifically, if the difference in specific gravity between the phosphors of highest specific gravity and the ones of lowest specific gravity exceeds 3.5, as the phosphors 6 of a plurality of different specific gravities are dispersed in the light transmitting member 5 and left intact for a certain period of time, the phosphors of high specific gravity 6a in particular are prone to accumulate in strata earlier in the light transmitting member 5. As a result, the light emitted from the light-emitting element 4 is cut off by the phosphors 6a collected on the bottom side of the light transmitting member 5, and therefore the phosphors 6a and 6b collected on the upper side of the light transmitting member 5 cannot be excited with ease. This makes it difficult to strike a proper radiation-intensity balance among the light beams emitted from the individual phosphors 6. The light-emitting apparatus 1 will thus be incapable of emitting light with the desired color temperature.

Used as the phosphors 6 to be admixed in the light transmitting member 5 are inorganic and organic phosphors that exhibit for example blue-color light emission, red-color light emission, and green-color light emission individually, by exploiting recombination of electrons, under excitation by the light emitted from the light-emitting element 4. By blending these phosphors 6 in a given proportion, it is possible to put out light having the desired emission spectrum and color.

In the light-emitting apparatus 1B, the light-emitting element 4 is preferably designed to emit light exhibiting an emission spectrum having a peak wavelength at 450 nm or below. Moreover, the light transmitting member 5 is preferably made of silicone resin or fluorine resin. In this way, several advantages are gained: an undesirable decrease in the transmittance of the light transmitting member 5 ascribable to the high-energy light of short wavelength emitted from the light-emitting element 4 can be prevented effectively; an undesirable decrease in the strength of bonding between the light-emitting element 4 and the base body 2 can be prevented effectively; the base body 2 and the frame body 3 can be prevented effectively; and the phosphors 6 are able to allow conversion into light of varying colors, for example white-color light, blue-color light, etc.

Further, it is preferable that the phosphors 6 has a specific gravity ranging from 3.3 to 7.2. In a case where the specific gravity of the phosphor 6 is lesser than 3.3, a difference in specific gravity between the phosphors 6a having the highest specific gravity and the other phosphors becomes too large for the light-emitting apparatus to put out light having a desired wavelength spectrum since it becomes difficult to disperse the plural kinds of phosphors 6 uniformly in the light transmitting member 5. In a case where the specific gravity of the phosphor 6 exceeds 7.2, the phosphors 6a having large specific gravity are sequentially laminated when the light transmitting member 5 and the phosphors 6 are admixed. In this case, an efficiency of wavelength conversion effected by the phosphors on a bottom layer becomes larger while an efficiency of wave length conversion caused by the phosphors on a top layer becomes smaller. Therefore, a proportion of admixed light from the phosphors emitted from the light-emitting apparatus varies so that light having the desired wavelength spectrum cannot be put out. Moreover, the density of the phosphors 6 in the light transmitting material becomes larger, and the phosphors 6 on their own becomes impediments to light propagation so that propagation loss is increased. Therefore, it becomes difficult for light of the phosphors 6 to be efficiently put out to the outside of the light-emitting apparatus.

The light-emitting apparatuses 1, 1A, 1B of the invention may be used to constitute an illuminating apparatus. For example, the illuminating apparatus is constructed by setting up a single piece of the light-emitting apparatus in a predetermined arrangement, or by setting up a plurality of the light-emitting apparatuses in a lattice, staggered, or radial arrangement, or by setting up a plurality of concentrically-arranged circular or polygonal light-emitting apparatus units, each of which is composed of a plurality of the light-emitting apparatuses, in a predetermined arrangement. In the illuminating apparatus thus constructed, light emission is effected by exploiting recombination of electrons in the light-emitting element 4 composed of a semiconductor. Thus, the illuminating apparatus has the advantage, in terms of power saving and long lifetime, over a conventional illuminating apparatus for effecting light emission through electrical discharge. The illuminating apparatus can accordingly be designed as a compact, low heat-generation construction. As a result, variation in the center wavelength of the light emitted from the light-emitting element 4 can be suppressed; wherefore the illuminating apparatus is capable of irradiating light with stable radiation light intensity and stable radiation light angle (luminous intensity distribution) for a longer period of time. Moreover, unevenness in color and unbalanced illumination distribution can be prevented from occurring on a to-be-irradiated surface.

Further, by setting up the light-emitting apparatuses 1, 1A, 1B of the invention in a predetermined arrangement as light sources, followed by arranging around the light-emitting apparatuses such a component as is optically designed in a given configuration, for example a reflection jig, an optical lens, or a light diffusion plate, it is possible to realize an illuminating apparatus which is capable of emitting light with given luminous intensity distribution.

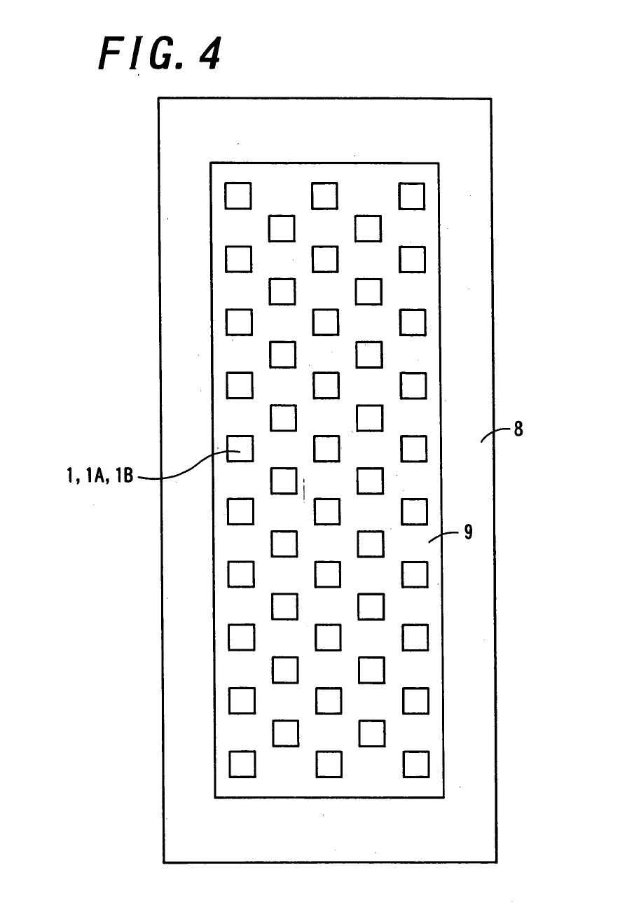

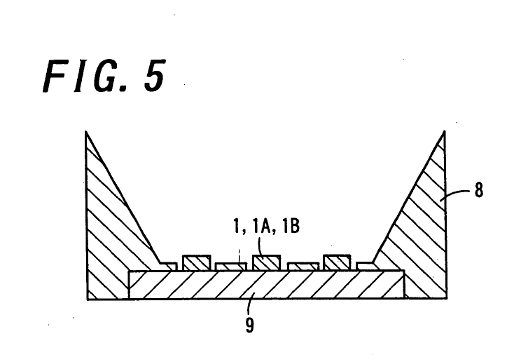

FIG. 4 is a top view showing an illuminating apparatus in accordance with a fourth embodiment of the invention. FIG. 5 is a sectional view of the illuminating apparatus shown in FIG. 4. For example, as shown in FIGS. 4 and 5, an illuminating apparatus is composed of a plurality of light-emitting apparatuses 1, 1A, 1B arranged in a plurality of rows on a rectangular light-emitting apparatus drive circuit board 9; and a reflection jig 8 optically designed in a given configuration, which is disposed around the light-emitting apparatuses 1, 1A, 1B. In this construction, adjacent arrays of a plurality of the light-emitting apparatuses 1, 1A, 1B are preferably so arranged as to secure as sufficient a spacing as possible between the adjacent light-emitting apparatuses 6, that is; the light-emitting apparatuses 1, 1A, 1B are preferably staggered. If the light-emitting apparatuses 1, 1A, 1B are disposed in a lattice arrangement, that is; the light-emitting apparatuses 1, 1A, 1B acting as light sources are arranged rectilinearly, glare will be intensified. An illuminating apparatus having such a lattice arrangement of the light-emitting apparatuses 1. 1A, 1B tends to bring discomfort or trouble to human eyes. In view of the foregoing, by disposing the light-emitting apparatuses 1, 1A, 1B in the staggered arrangement, it is possible to suppress glare and thereby reduce discomfort or trouble to human eyes. Another advantage is that, since the spacing between the adjacent light-emitting apparatuses 1, 1A, 1B can be made as long as possible, it will be possible to effectively suppress thermal interference between the adjacent light-emitting apparatuses 1, 1A, 1B. Hence, heat confinement within the light-emitting apparatus drive circuit board 9 carrying the light-emitting apparatuses 1, 1A, 1B can be avoided; wherefore heat can be dissipated from the light-emitting apparatuses 1, 1A, 1B to the outside with high efficiency. As a result, it is possible to provide a long-life illuminating apparatus that has little adverse effect on human eyes and offers stable optical characteristics for a longer period of time.

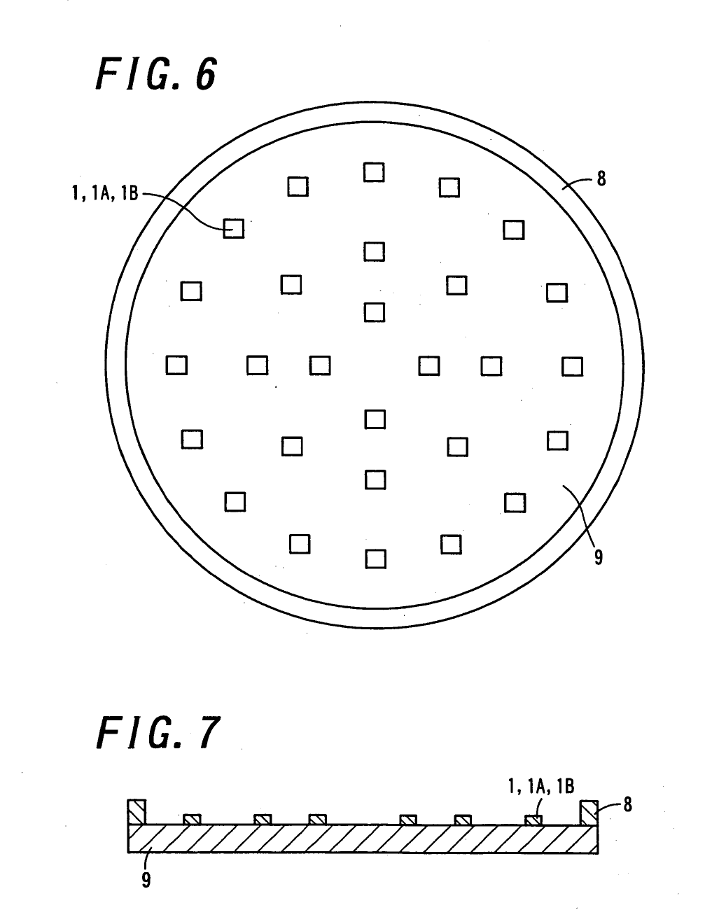

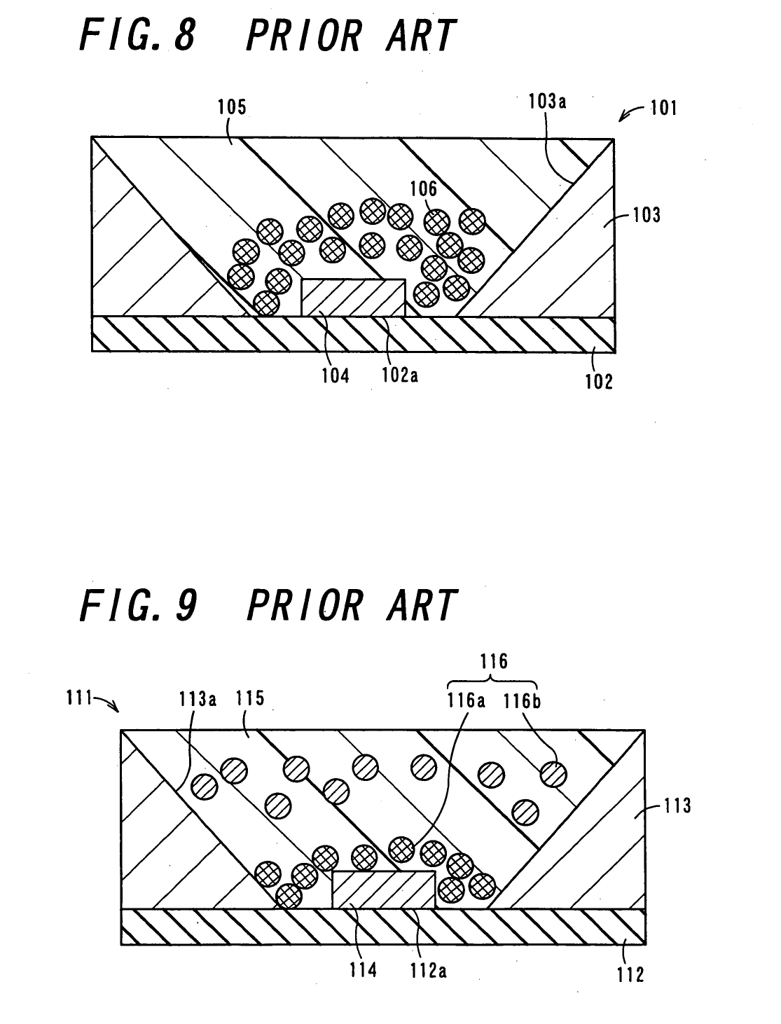

FIG. 6 is a top view showing an illuminating apparatus in accordance with a fifth embodiment of the invention. FIG. 7 is a sectional view of the illuminating apparatus shown in FIG. 6. As shown in FIGS. 6 and 7, an illuminating apparatus of another type is constituted by concentrically arranging, on the circler light-emitting apparatus drive circuit board 9, a plurality of circular or polygonal light-emitting apparatus units, each of which is composed of a plurality of the light-emitting apparatuses 1, 1A, 1B. In this construction, it is preferable that, in a single circular or polygonal light-emitting apparatus unit, the light-emitting apparatuses 1, 1A, 1B are so arranged that the number thereof becomes larger gradually from the center to the outer edge of the illuminating apparatus. This makes it possible to arrange the light-emitting apparatuses 1, 1A, 1B as many as possible while securing a sufficient spacing between the adjacent light-emitting apparatuses 1, 1A, 1B, and thereby enhance the illumination level of the illuminating apparatus. Moreover, by lowering the density of the light-emitting apparatuses 1, 1A, 1B in the midportion of the illuminating apparatus, it is possible to avoid heat confinement in the midportion of the light-emitting apparatus drive circuit board 9. Therefore, in the light-emitting apparatus drive circuit board 9, uniform temperature distribution can be observed. Thus, heat can be transmitted to an external electric circuit board or a heat sink with the illuminating apparatus with high efficiency; wherefore temperature rise can be suppressed in the light-emitting apparatuses 1, 1A, 1B. As a result, it is possible to provide a long-life illuminating apparatus in which the light-emitting apparatuses 1, 1A, 1B can be operated with stability for a longer period of time.

The illuminating apparatus such as shown herein will find a wider range of applications including: general-purpose lighting fixtures for indoor or outdoor use: illumination lamps for chandeliers; home-use lighting fixtures; office-use lighting fixtures; store-use lighting fixtures; lighting fixtures for display; street lighting fittings; guidance lights; signal devices; lighting fixtures for stage or studio use; advertisement lights; illumination poles; underwater illumination lights; stroboscopic lights; spotlights; security lighting fixtures embedded in electric poles or the like; lighting fixtures for emergency; electric torches; electric bulletin boards; dimmers; automatic blink switches; backlights for display or other purposes; motion picture devices; ornamental articles; illuminated switches; light sensors; lights for medical use; and vehicle-mounted lights.

### EXAMPLES

Hereinafter, a description will be given as to example of the light-emitting apparatus 1 of the invention with reference to FIG. 1.

### Example 1

At first, as the base body 2, an alumina ceramics substrate was prepared for use.

The base body 2 is composed of a rectangular plate which is 3.5 mm in length×3.5 mm in width×0.5 mm in thickness. The base body 2 has, at the center of its top surface, the placement portion 2a for emplacing thereon the light emitting element 4. Moreover, in the base body 2, a wiring conductor composed of a W-made metallized wiring line is so disposed as to extend from the placement portion 2a to the under surface thereof.

Moreover, the frame body 3 was formed in the shape of a circular cylinder, the dimensions of which are: 3.5 mm in exterior diameter; 1.5 mm in height; 3.3 mm in diameter of upper opening; and 0.5 mm in diameter of lower opening.

Next, the 0.08 mm-thick light-emitting element 4 for emitting near-ultraviolet light was, at the Au—Sn bump disposed in its electrode, bonded to the wiring conductor. Concurrently, the frame body 3 was joined to the outer periphery of the top surface of the base body 2 so as to surround the light-emitting element 4 with use of a resin adhesive.

After that, as the light transmitting member 5, silicone resin was charged into the area surrounded by the base body 2 and the frame body 3 by a dispenser, until the level of the silicone resin reached the uppermost end of the inner peripheral surface of the frame body 3. The silicone resin contains the phosphors 6 of three different types that exhibit red-color light emission, green-color light emission, and blue-color light emission, individually. The pre-cured viscosity of the silicone resin is set at 1.7 Pa.s. Whereupon, a sample of the light-emitting apparatus was fabricated.

The phosphors 6 for red-color light emission (La₂O₂S:Eu) have a density of 5.8 g/cm³; those for green-color light emission (BaMgAl₁₀O₁₇:Eu) have a density of 3.8 g/cm³; and those for blue-color light emission (BaMgAl₁₀O₁₇:Eu, Mn) have a density of 3.8 g/cm³. These three different types of the phosphors 6 were blended together so as for the color temperature of light emitted from the light-emitting apparatus to be 6500 K. The blended phosphors 6 were then admixed in the light transmitting member 5 and stirred uniformly. Lastly, the light transmitting member 5 was charged inside the frame body 3 so as to cover the light-emitting element 4.

There were fabricated four pieces of light-emitting apparatus samples that vary in terms of the length of time that the light transmitting member 5 is left to cure, that is; 0; 5; 10; and 20 minutes, respectively. Table 1 shows the data as to the relationship among the elapsed time, color temperature, and color rendering property.

TABLE 1

| Time that elapsed | Color rendering | Color temperature |
|---|---|---|
| before curing [m] | property | [K] |
| 0 | 63.07 | 6462 |
| 5 | 62.01 | 6370 |
| 10 | 61.8 | 6010 |
| 20 | 60.32 | 5220 |

As will be understood from Table 1, the longer the light transmitting member 5 is left to cure, the poorer the color rendering property. Furthermore, depending on the samples, the color temperature dropped below the target value, that is; 6000 K. This is because, as the light transmitting member 5 is left to cure for a prolonged period of time, the phosphors 6 precipitate steadily, with the result that the phosphors 6 are dispersed unevenly in the light transmitting member 5. If the light emitted from the light-emitting element 4 is subjected to wavelength conversion in this state, the desired color rendering property and color temperature cannot be attained.

### Example 2

Hereinafter, a description will be given as to example of the light-emitting apparatus 1B of the invention with reference to FIG. 3.

In the example 2, components configuring the base body 2 and the frame body 3 in the light-emitting apparatus 1B are the same as those used in the example 1.

In the same way as the example 1, the phosphors 6 for red-color light emission (La₂O₂S:Eu) have a density of 5.8 g/cm³; those for green-color light emission (BaMgAl₁₀O₁₇:Eu) have a density of 3.8 g/cm³; and those for blue-color light emission (BaMgAl₁₀O₁₇:Eu, Mn) have a density of 3.8 g/cm³. These three different types of the phosphors 6 were blended together so as for the color temperature of light emitted from the light-emitting apparatus 1 to be 6500 K.

Moreover, as the light transmitting member 5, silicone resin materials of varying pre-cured viscosities, that is; 0.3; 0.4; 1.3; 10; 50; and 55 Pa.s were prepared for use. In each silicone resin material is admixed the phosphors 6 of three different types that exhibit red-color light emission, green-color light emission, and blue-color light emission, individually. After the blended phosphors 6 were stirred uniformly, the light transmitting member 5 was charged inside the frame body 3 so as to cover the light-emitting element 4. The charged light transmitting member 5 was then left to cure for five minutes.

Table 2 shows the evaluation result data as to the color temperature and color rendering property with respect to the pre-cured viscosity of each silicone resin material, as observed in the light-emitting apparatus 1B thus far described.

TABLE 2

| Resin viscosity | Color rendering | Color temperature |
|---|---|---|
| [Pa · s] | property | [K] |
| 55* | 85.23 | 7220 |
| 50 | 88.1 | 6922 |
| 10 | 86.59 | 6562 |
| 1.3 | 86.28 | 6253 |
| 0.4 | 84.17 | 6009 |
| 0.3* | 81.73 | 5809 |

Values indicated with asterisk are regarded as being not within the scope of the invention

As will be understood from Table 2, in one light-emitting apparatus 1B in which the silicone resin has a pre-cured viscosity of 0.3 Pa.s, there was a color-temperature deviation of greater than 10% from the target value for the intended color temperature, that is; 6500 K. Meanwhile, in the other light-emitting apparatus 1B in which the silicone resin has a pre-cured viscosity of 55 Pa.s, there was also a color-temperature deviation of greater than 10% from the target value of 6500 K. This is because, since the silicone resin exhibits unduly high pre-cured viscosity, the phosphors 6 cannot be dispersed uniformly in the entire silicone resin, which leads to unbalanced gathering of the phosphors 6.

By contrast, it has been confirmed that the light-emitting apparatus 1 of the invention, in which the silicone resin ranges in pre-cured viscosity from 0.4 to 50 Pa.s, is excellent in that the deviation of color temperature falls within 10%.

### Example 3

In the example 3, components configuring the base body 2 and the frame body 3 in the light-emitting apparatus are the same as those used in the example 1.

The phosphors 6 for red-color light emission (La₂O₂:Eu) have a density of 5.8 g/cm³; those for green-color light emission ((BaMgAl)₁₀O₁₂:Eu, Mn) have a density of 3.8 g/cm³; and those for blue-color light emission ((Sr, Ca, Ba, Mg)₁₀(PO₄)₆O₁₂:Eu) have a density of 3.8 g/cm³. These three different types of the phosphors 6 were blended together.

Moreover, as the light transmitting member 5, silicone resin having pre-cured viscosities of 1.7 Pa.s is prepared for use. The silicone resin is vacuum-defoamed in a non-cured state by a vacuum defoamer. To the vacuum-defoamed silicone resin, admixed are the phosphors 6 admixed so as to put out desired visible light therein, so that a volume of the phosphors is 1/30, 1/24, 1/18, 1/15, 1/12, 1/6, 1/5 times as much as that of the silicone resin, respectively. In other words, the vacuum-defoamed silicone resin is admixed so that volume proportion of the phosphors and the silicone resin (the phosphors:the silicone resin) is 1:30, 1:24, 1:18, 1:15, 1:12, 1:6, 1:5, respectively. Then, the silicone resin containing the phosphors 6 is respectively stirred and vacuum-defoamed by the vacuum defoamer.

These non-cured silicone resin containing the phosphors is applied to a smooth surface of a glass plate to make a thickness of 0.8 mm, and cured with heat at 150° C. for 10 minutes to respectively make a form of plates. Then, the cured silicone resin in the form of plates is peeled off the glass plate. The phosphor layer is formed by respectively making a desired form of the silicone resin in the form of plate by punching with use of a belt punch or the like. These phosphor layer is arranged on the upper side of the light-emitting element 4 so as to cover the opening of the frame body 3. Thus, provided is the light-emitting apparatus capable of putting out desired visible light by blending colors of light from the phosphors 6, excited by light emitted from the light-emitting element 4.

The light-emitting apparatus thus constructed is operated to measure a total luminous flux from the light-emitting apparatus by an integrating sphere, and a chromaticity coordinate is set up. Note that the same excitation light source is used in each light-emitting apparatus. The result data is shown in Table 3.

TABLE 3

| Phosphors:silicone | | |
|---|---|---|
| resin (volume | Total luminous | Ratio relative to |
| proportion) | flux [lm] | maximum value [%] |
| 1:5* | 2.29 | 0.776 |
| 1:6 | 2.52 | 0.854 |
| 1:12 | 2.81 | 0.953 |
| 1:15 | 2.95 | 1 |
| 1:18 | 2.79 | 0.946 |
| 1:24 | 2.46 | 0.834 |
| 1:30* | 2.16 | 0.732 |

Values indicated with asterisk are regarded as being not within the scope of the invention

As will be understood from Table 3, in a case where the phosphor layer made of the light transmitting member containing the phosphors has a thickness ranging from 0.3 to 1.5 mm, and where the phosphors have a volume of 1/24 to 1/6 times as much as that of the light transmitting member, it was found that wavelength conversion can be performed on light emitted from the light-emitting element by the phosphors with high efficiency, and the visible light on which wavelength conversion is performed by the phosphors can also be put out to the outside of the light-emitting apparatus.

It is to be understood that the application of the invention is not limited to the specific embodiments described heretofore, and that many modifications and variations of the invention are possible within the spirit and scope of the invention. For example, a platy light transmitting lid or an optical lens capable of condensing and diffusing the light emitted from the light-emitting element 4 in a given manner may additionally be bonded to the top surface of the frame body 3 with use of solder or a resin adhesive. This makes it possible to produce light at the desired radiation angle and also to improve the immersion resistance in the interior of the light-emitting apparatuses 1, 1A, 1B, which contributes to enhancement of the long-term reliability. Moreover, the inner peripheral surface 3a of the frame body 3 may be so shaped as to have a flat (rectilinear) sectional profile or a circular arc (curved) sectional profile. With the circular arc sectional profile, the light emitted from the light-emitting element 4 can be reflected thoroughly, and thereby light with high directivity is allowed to radiate out evenly.

Note also that the illuminating apparatus embodying the invention may be constituted by either setting up a plurality of the light-emitting apparatuses 1, 1A, 1B in a predetermined arrangement or setting up a single piece of the light-emitting apparatuses 1, 1A, 1B in a predetermined arrangement.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

1. A light-emitting apparatus comprising:
a light-emitting element;
a base body having, on its top surface, a placement portion for emplacing thereon the light-emitting element;
a frame body attached to the top surface of the base body so as to surround the placement portion;
a light transmitting member disposed inside the frame body so as to cover the light-emitting element; and
phosphors contained in the light transmitting member, which performs wavelength conversion on the light emitted from the light-emitting element,
wherein the light transmitting member has a pre-cured viscosity ranging from 0.4 to 50 Pa.s.

2. The light-emitting apparatus of claim 1, wherein the phosphors have a density ranging from 3.8 to 7.3 g/cm³.

3. The light-emitting apparatus of claim 1, wherein the phosphors are composed of a plural kinds of substances.

4. The light-emitting apparatus of claim 3, wherein the phosphors are so prepared that a difference in specific gravity between the ones of highest specific gravity and the ones of lowest specific gravity is kept at 3.5 or below.

5. The light-emitting apparatus of claim 1, wherein a phosphor layer made of the light transmitting member containing the phosphors has a thickness ranging from 0.3 to 1.5 mm and a volume of 1/24 to 1/6 times as much as al volume of the light transmitting member.

6. The light-emitting apparatus of claim 1, wherein the phosphors have an average grain diameter ranging from 1 to 50 μm.

7. The light-emitting apparatus of claim 1, wherein the light-emitting element is designed to emit light exhibiting an emission spectrum having a peak wavelength at 450 nm or below, and
wherein the light transmitting member is made of silicone resin or fluorine resin.

8. A method for manufacturing the light-emitting apparatus, comprising the steps of:
attaching a frame body on a top surface of a base body having a placement portion for emplacing a light-emitting element, so as to surround the placement portion;
emplacing the light-emitting element on the placement portion; and
uniformly admixing phosphors in alight transmitting member having a pre-cured viscosity ranging from 0.4 to 50 Pa.s, charging the light transmitting member containing the phosphors inside the frame body so as to cover a surface of the light-emitting element, and thereafter curing the light transmitting member within ten minutes.

9. An illuminating apparatus constructed by setting up the light-emitting apparatus of claim 1 in a predetermined arrangement.
